(19) United States
(12) Patent Application Publication
(10) Pub. No.: US 2008/0014689 A1
(43) Pub. Date: Jan. 17, 2008

(54) Method for making planar nanowire surround gate mosfet

(75) Inventors: C. Rinn Cleavelin, Lubbock, TX (US); Weize W. Xiong, Austin, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED

(21) Appl. No.: 11/482,042

(22) Filed: Jul. 7, 2006

(51) Int. Cl. H01L 21/8234

(52) U.S. Cl. 438/197

(57) ABSTRACT

Embodiments provide a method of fabricating a plurality of planar nanowires surround gate semiconductor device. The planar nanowires can be formed between a source and a drain over an insulating layer of a semiconductor substrate. A gate stack can be grown or deposited all-around the planar nanowires. The gate stack can then be etched and patterned. During this process, the planar nanowires are severed between the gate and the source, and between the gate and the drain, leaving portions of the gate-all-around planar nanowires remain between the source and the drain and serve as the active region of the channel. The remaining gate-all-around planar nanowires can be epitaxially regrown to reconnect to the source and the drain.

### DESCRIPTION OF THE INVENTION

1. Field of the Invention

The present invention is directed to metal-oxide-semiconductor field-effect (MOSFET) devices, and more particularly, to gate-all-around (or surround gate) MOSFET devices.

2. Background of the Invention

Multigate metal-oxide-semiconductor field-effect transistors (MOSFETs) have been considered the most promising device for complementary MOS (CMOS) technology scaling into nanoscale generations due to their merits, such as a high immunity to short channel effects. Compared to other multigate MOSFETs, such as double gate and tri-gate structures, the gate-all-around (GAA) (or surround gate) configuration is considered to be a highly scalable structure and offers superior short channel control.

A GAA structure typically has a gate that surrounds or wraps around the conducting channel of the device. This structure effectively improves the capacitance coupling between the gate and the channel. With the GAA structure, the gate gains significant influence on the channel potential, and therefore, improves the suppression of short-channel effects. A GAA structure typically allows the gate length to be scaled down by about 50% or more compared to a double-gate structure.

There are several different ways to implement a GAA transistor structure. For example, the transistor channel can be oriented vertically or horizontally to form a vertical MOSFET or a planar MOSFET.

In the case for a planar MOSFET, many of the known designs utilize horizontally oriented channels that have a square or rectangular shaped cross-section. When the channel cross-section is rectangular or square, enhanced field effects at the corners of the rectangle may cause that part of the transistor to turn on earlier (i.e., having a lower threshold voltage) than parts of the transistor at the flat sides of the rectangular channel cross-section. Unfortunately, this can result in a parasitic off-state leakage.

Attempts at forming a more circular channel cross-section rather than a rectangular channel cross-section are conventionally made by oxidizing the silicon beam in the channel to round the corners of the rectangular channel cross-section. However, this requires excessive oxide formation about the channel.

Recently, attempts at forming a more circular channel cross-section have been accomplished by annealing the channel to form a nanowire with a rounded cross-section. However, these methods have a limited channel width.

Moreover, in order to make the gate electrode surround the active region at the channel part, a buried insulating layer under the active region must be isotropically etched to form an under-cut. In this process, the isotropic etching removes not only the channel's bottom of the active region, but also bottoms of the source/drain regions. Thus, when the gate electrode layer is formed, the gate electrode is formed at the bottoms of not only the channel but also the source/drain regions. This can lead to a large parasitic capacitance in the device.

In order to avoid this problem, one or more layers of silicon germanium may be added to the channel part of the device. Isotropic etching may then be used to selectively remove the silicon germanium layer to form a cavity under active part of the channel region. However, this adds complexity to the processing and reduces layout efficiency, because of the damage caused during the isotropic etching of the silicon germanium.

### SUMMARY

According to various embodiments, the present teachings include a method of fabricating a semiconductor device including providing a semiconductor substrate comprising an insulating layer overlaid by a semiconductor layer, wherein the semiconductor layer comprises a source region separated from a drain region by a gap. A plurality of planar nanowires can be formed in the gap, wherein the planar nanowires contact the source region and the drain region. A gate stack can be formed in the gap, wherein the gate stack comprises the planar nanowires. The gate stack can be etched to sever the planar nanowires from the source region and from the drain region while leaving portions of the nanowires in the gap, wherein the portions of the nanowires in the gap form a channel region. The source region and the drain region can then be reconnected to the portions of the nanowires in the gap.

According to various embodiments, the present teachings also include a method of fabricating a semiconductor device. In the method, a source region and a drain region separated by a gap can be formed over a semiconductor substrate. At least one planar semiconductor structure can be formed in the gap, wherein the at least one planar semiconductor structure contacts the source region and the drain region. A dielectric layer can be formed to surround the planar semiconductor structure. A conductive layer can then be formed to surround the dielectric layer, wherein the planar semiconductor structure, the dielectric layer, and the conductive layer form a gate-all-around structure. The at least one planar semiconductor structure can be severed from the source region and the drain region, wherein a portion of the planar semiconductor structure remains in the gap. A first semiconductor structure can be formed to contact the planar semiconductor structure and the source region. A second semiconductor structure can be formed that contacts the planar semiconductor structure and the drain region.

According to various embodiments, the present teachings further include a semiconductor device. The semiconductor device includes a source, a drain and a gate coupled to the source and the drain by a plurality of nanowires, wherein each of the nanowires comprises a semiconductor structure surrounded by a dielectric layer, and the wherein each of the dielectric layers is surrounded by a conductive layer.

Additional features of the invention will be set forth in part in the description which follows, and in part will be obvious from the description, or may be learned by practice of the invention. The features of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments of the invention and together with the description, serve to explain the principles of the invention. In the figures:

FIG. 1A shows a top-down view of a semiconductor device in accordance with the present teachings;

FIGS. 1B-1C show the cross-sectional views along the direction of X-X′ and Y-Y′, respectively, for the device shown in FIG. 1A;

FIG. 2A shows a top-down view of a semiconductor device in accordance with the present teachings, where a plurality of planar semiconductor fins are formed;

FIG. 2B shows the cross-sectional view along the X-X′ direction for the device shown in FIG. 2A;

FIG. 3A shows a top-down view of a semiconductor device in accordance with the present teachings, where a plurality of planar semiconductor nanowires are formed;

FIGS. 3B-3C show cross-sectional views along the direction of X-X′ and Y-Y′, respectively, for the device shown in FIG. 3A;

FIG. 4 shows a top-down view of a semiconductor device in accordance with the present teachings, where a gate stack is formed to cover and fill the structure of the semiconductor device;

FIG. 5 shows a top-down view of a semiconductor device with a patterned gate stack in accordance with the present teachings;

FIG. 6A shows a top-down view of a semiconductor device in accordance with the present teachings, where portions of the planar nanowires remain in the patterned gate stack, but are disconnected from the source and the drain;

FIG. 6B shows the cross-sectional view along the X-X′ direction of the semiconductor device shown in FIG. 6A;

FIG. 7 shows a top-down view of a semiconductor device in accordance with the present teachings, where the portions of the planar nanowires are reconnected to the source and the drain.

### DESCRIPTION OF THE EMBODIMENTS

Embodiments of the present invention provide a method of fabricating a plurality of planar nanowires surround gate semiconductor device. The planar nanowires can be formed between a source and a drain over an insulating layer of a semiconductor substrate. The gate stack can then be grown or deposited all-around the planar nanowires. The gate stack can then be etched and patterned. During this process, the planar nanowires can be severed between the gate and the source, and between the gate and the drain, leaving portions of the gate-all-around planar nanowires remaining between the source and the drain. These portions can serve as the active region of the channel. The remaining gate-all-around planar nanowires can then be epitaxially regrown to reconnect to the source and the drain.

Reference will now be made in detail to the exemplary embodiments of the invention, examples of which are illustrated in the accompanying drawings. Wherever possible, the same reference numbers will be used throughout the drawings to refer to the same or like parts.

In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, merely exemplary.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

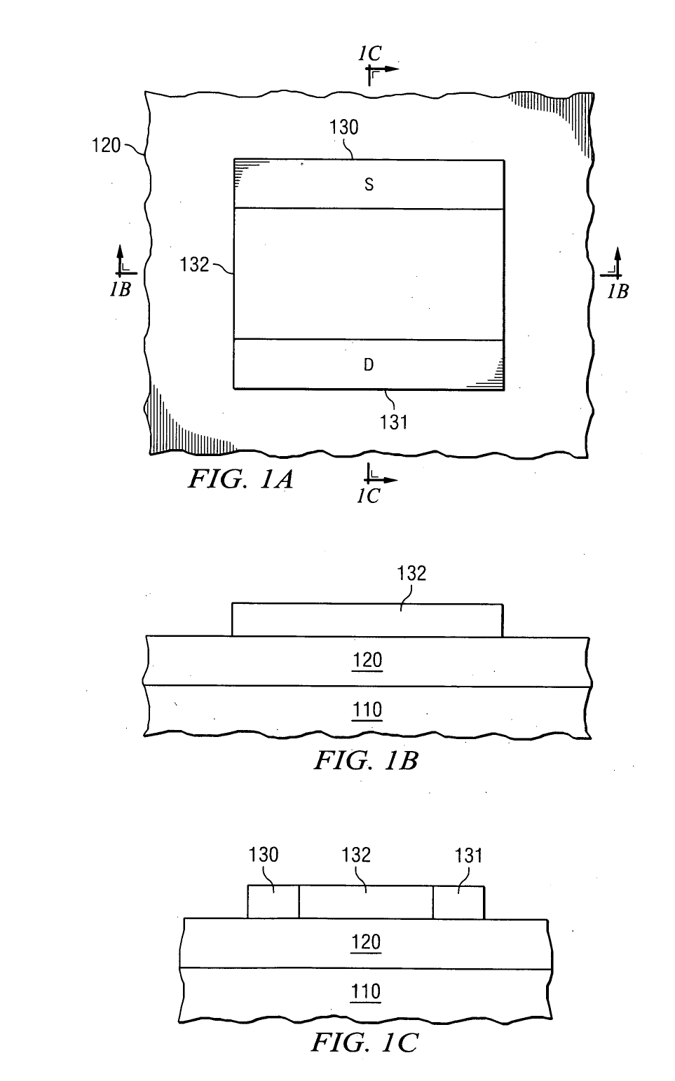

FIG. 1A shows a top-down view of a semiconductor device 100. FIGS. 1B-1C show the cross-sectional views along the direction of 1B-1B and 1C-1C, respectively, for the device 100 shown in FIG. 1A. As illustrated in FIGS. 1A-1C, semiconductor device 100 includes a semiconductor substrate 110, such as a silicon, overlaid by an insulating layer 120. Overlaying the insulating layer 120 is a semiconductor layer including a source 130 separated from a drain 131 by a gap 132.

The insulating layer 120 formed on the semiconductor substrate 110 can be any dielectric insulator, for example, silicon oxide, silicon nitride, silicon oxynitride, or other known dielectric. Several commercial Silicon-on-Insulator (SOI) methods can be used to fabricate the insulating layer 120. For example, a silicon oxide layer can be thermally grown on the semiconductor substrate 110 in an O₂ or H₂O ambient. Alternatively, a silicon nitride layer can be formed by nitrifying the semiconductor substrate 110 in a nitrogen ambient. Moreover, a silicon oxynitride layer can be deposited on the surface of semiconductor substrate 110 by chemical vapor deposition (CVD). The thickness of the silicon oxide or silicon nitride layer can be from about 10 angstroms to a few thousand angstroms.

The source 130, the drain 131 and the gap 132 can be formed in a semiconductor layer that is formed over the insulating layer 120. When the semiconductor layer is formed of single crystal silicon, a silicon-on-insulator (SOI) substrate can be used. In certain embodiments, the semiconductor layer can be germanium (Ge), an alloy semiconductor, such as silicon-germanium (SiGe), silicon-germanium carbon (SiGeC), silicon-carbon (SiC), or a compound semiconductor, such as gallium arsenide (GaAs), gallium nitride (GaN), indium antimonide (InSb), gallium indium arsenide (GaInAs). In some embodiments, a channel is then formed in the gap 132 between the source 130 and the drain 131.

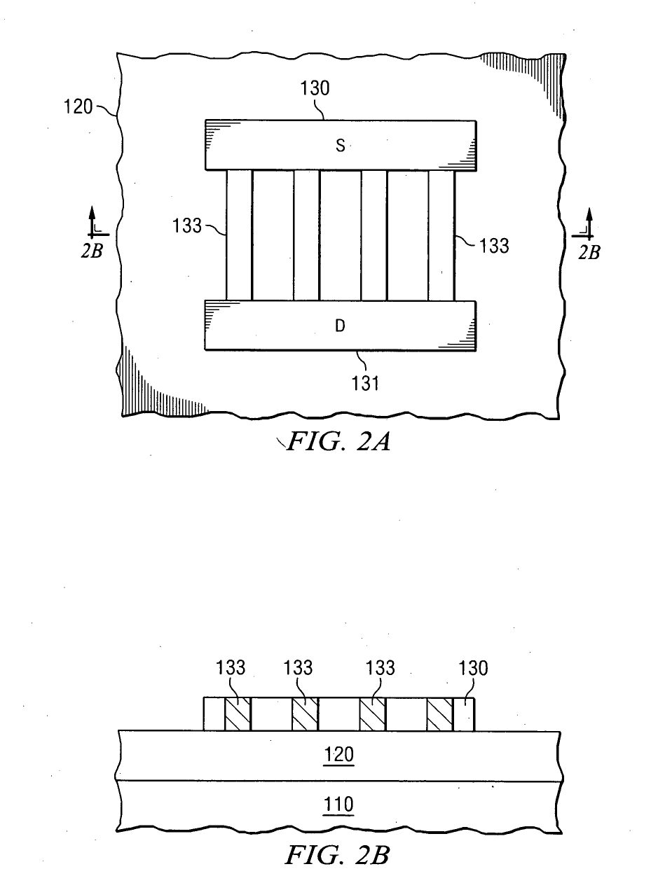

FIG. 2A shows the top-down view of the semiconductor device 100, where a plurality of planar semiconductor fins 133 are formed in the gap 132. Typically, one end of each of the fins contacts the source 130 and another end contacts the drain 131. FIG. 2B shows the cross-sectional view along the 2B-2B direction for the device shown in FIG. 2A. As illustrated in FIG. 2A-2B, the patterned planar semiconductor fins 133 can be rectangular or square and can have sharp edges or corners. Moreover, one side of the fins contacts the insulating layer 120.

The planar semiconductor fins 133 can be formed in one or more steps. For example, the planar semiconductor fins 133 can be formed by patterning the semiconductor layer overlying the insulating layer 120 using a lithographical and etching process, such as a wet etching process or a dry etching process (e.g. plasma etching or reactive ion etching (RIE). Lithographical and the etching process are well-known to one of the ordinary skills in the art.

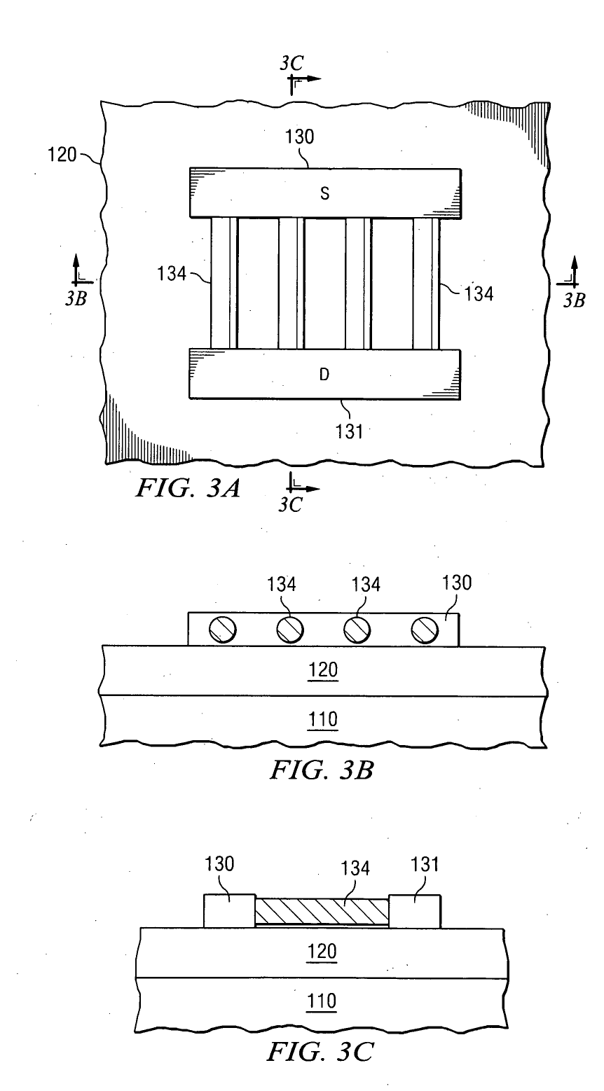

FIG. 3A shows the top-down view of the semiconductor device 100, where a plurality of planar semiconductor nanowires 134 are formed from the planar semiconductor fins 133 (shown in FIG. 2A). FIGS. 3B-3C show the cross-sectional views for the semiconductor device 100 along the direction of 3B-3B and 3C-3C, respectively. As illustrated in FIGS. 3A-3C, the nanowires 134 include a circular cross-section and are suspended above the insulating layer 120. Moreover, the nanowires 134 contact to the source 130 on one end and the drain 131 on the other end.

According to various embodiments, the planar semiconductor nanowires 134 can be formed by annealing the planar semiconductor fins 133 in a hydrogen gas ambient. The annealing process encourages the migration of semiconductor atoms in the semiconductor fins 133 and facilitates the rounding of planar nanowires 134 into more rounded cross-sections. The annealing temperature can range from about 600 to about 1000 degrees Celsius. And, the annealing pressure can range from about a few mTorr to about 760 mTorr. For example, the semiconductor fins 133 shown in FIG. 2A can be annealed at the temperature of about 900 degrees Celsius and at a pressure of about 15 mTorr to form and round the planar semiconductor nanowires 134.

The diameter of the annealed nanowires 134 can be from about 40 nm to less than about 5 nm. After the annealing process, the nanowires 134 can be suspended above the insulating layer 120 as shown in FIGS. 3B-3C.

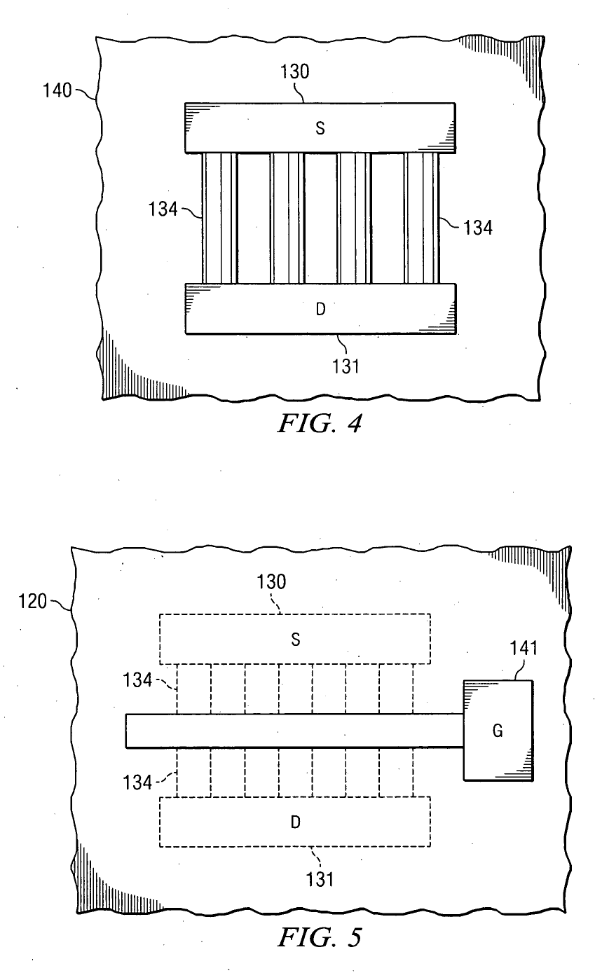

FIG. 4 shows a gate stack 140 formed to cover and fill the structure of the semiconductor device 100. That is, the gate stack 140 may fill around the source 130, the drain 131, and the planar nanowires 134 suspended over the insulating layer 120 between the source 130 and the drain 134.

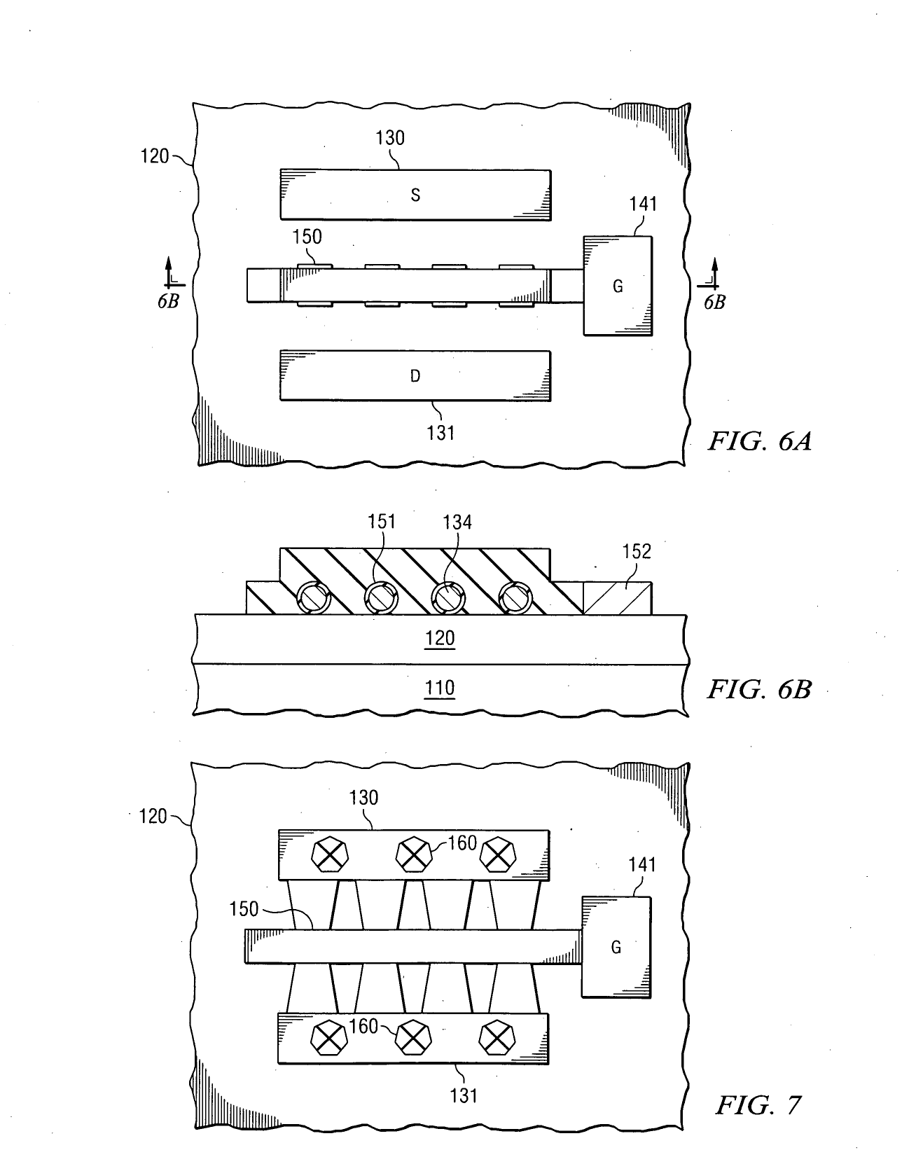

The gate pattern 141 can be formed by patterning the gate stack 140 and source and drain regions. For example, a lithographical process and a subsequent etching process can be used to pattern the gate stack 140 to form a certain shaped gate, such as the T-shaped gate 141 as shown in FIG. 5 post pattern and FIGS. 6A and 6B post etch shows that the gate 141 includes two layers, that is, a gate dielectric 151 and a gate electrode 152.

The gate dielectric 151 can be any high-k dielectric material. For example, the gate dielectric 151 can be a thermal oxide layer or a thermal nitride layer that is formed through thermal oxidation or thermal nitrification. Alternatively, the gate dielectric 151 can comprise at least one of: a transition metal oxide, such as tantalum oxide (Ta₂O₅), titanium oxide (TiO₂), zirconium oxide (ZrO₂), hafnium oxide (HfO₂), gadolinium oxide (Ga₂O₃), scandium oxide (Sc₂O₃), a silicate alloy, such as zirconium silicate alloy or hafnium silicate alloy, or a complex oxide, such as gadolinium scandium oxide (GdScO₃), dysprosium oxide (DyScO₃) or hafnium titanium oxide (HfTiO₄), and other high k dielectrics. The gate dielectric 151 can be formed by, for example, CVD techniques or atomic layer deposition (ALD) techniques.

The gate electrode 152 can then be stacked on the gate dielectric 151. The gate electrode 152 can be formed of any conductive materials, such as a metal including copper, gold, platinum, palladium, aluminum, ruthenium, titanium or tantalum, a metal compound including tantalum carbide (TaC), tantalum nitride (TaN), titanium nitride (TiN), tantalum silicon nitride (TaSiN)), or a semiconductor material (e.g. poly-silicon or poly-silicon-germanium, and others. The deposition of the gate electrode 152 can be performed by physical vapor deposition (PVD) techniques such as e-beam techniques or sputtering, CVD techniques, ALD techniques, or electroplating techniques.

During the formation of the gate 141, etching processes can be performed in steps. For example, the gate dielectric 151 can be etched after an etching step of the gate electrode 152. The gate electrode 152 can be etched using a wet etching process or a dry etching process (e.g. plasma etching or RIE). The high k gate dielectric 151 can be etched using a dry etching process (e.g. plasma etching, RIE) or a wet etching process.

FIGS. 6A-6B also show that, the gate 141 comprises a plurality of portions of nanowires 150. As shown in FIG. 6A, the portions of nanowires 150 remain, but are disconnected from the source 130 and the drain 131. Moreover, as shown in FIG. 6B, each of the portions 150 is surrounded by a gate dielectric 151. In turn, the gate dielectric 151 can be surrounded by a gate electrode 152. The portions of nanowires 150 can be formed by severing the planar nanowires 134 during gate etch (as shown in FIG. 6A) to disconnect them from the source 130 and the drain 131 during the lithographical and the gate etching processes, which are well-known to one of ordinary skill in the art. After the severing process, the portions of nanowires 150 may comprise crystal facets that can serve as the seed structure for regrowing nanowires from the portions of nanowires 150. Moreover, the portions of nanowires 150 can serve as the active regions of the channel in devices, such as a MOSFET device.

FIG. 7 shows the top-down view of the semiconductor device, where the portions of nanowires 150 are regrown and reconnected to the source 130 and the drain 131. In addition, source and drain contacts 160 can be formed on the source 130 and the drain 131.

The portions 150 may be epitaxially regrown to reconnect them to the source 130 and the drain 131. The reconnection occurs in such a way that the epitaxial growth from the portions of nanowires 150 meet the epitaxial growth from the source 130 and drain 131. Typically, in epitaxial regrowth, a single crystalline material is desired to initiate the growth. Therefore, any single-crystalline material can be used as the re-grown nanowires in the portions 150. Materials in single crystalline form are known to those skilled in the art, and include, but are not limited to, silicon (Si), germanium (Ge), gallium (Ga), gallium arsenide (GaAs), indium phosphide (InP), silicon germanium (SiGe), gallium aluminum arsenide (GaAlAs), etc.

In some embodiments, the crystal orientation of the facets at portions of nanowires 150 can match the crystal orientation of the source and drain materials. Accordingly, during epitaxially regrowth, the crystals growing from both portions of nanowires 150 and the source 130 and the drain 131 can have the same crystal orientation. It should be noted that the crystal-matched regrowth can meet at the source and drain region other than in the gate. Therefore, any mismatches in plane during the epitaxial regrowth will be in the source and drain region. In some cases, such plane-mismatches can affect the performance of the device 100. For example, plane-mismatches may cause junction leakage. Yet any junction leakage can be terminated at the interface with the insulating layer 120, as shown in FIG. 7.

Other embodiments of the invention will be apparent to those skilled in the art from consideration of the specification and practice of the invention disclosed herein. Nonetheless, it is intended that the specification and examples be considered as exemplary only, with a true scope and spirit of the invention being indicated by the following claims.

What is claimed is:

1. A method of fabricating a semiconductor device comprising:
providing a semiconductor substrate comprising an insulating layer overlaid by a semiconductor layer, wherein the semiconductor layer comprises a source separated from a drain by a gap;
forming a plurality of planar nanowires in the gap, wherein the planar nanowires contact the source and the drain;
forming a gate stack in the gap, wherein the gate stack comprises the planar nanowires;
etching the gate stack to sever the planar nanowires from the source and from the drain, while leaving portions of the planar nanowires in the etched gate stack; and
reconnecting the source and the drain to the portions of the planar nanowires in the gate stack.

2. The method of claim 1, wherein providing the semiconductor substrate comprises providing buried silicon oxide layer as the insulating layer.

3. The method of claim 1, wherein forming the planar nanowires comprises:
forming semiconductor fins in the gap; and
annealing the semiconductor fins into circular cross-sections.

4. The method of claim 3, wherein annealing the semiconductor fins further comprises:
providing an ambient that comprises a gas comprising hydrogen at a temperature ranging from about 600 to about 1000 degrees Celsius, and at a pressure ranging from about a few mtorr to about 760 mTorr.

5. The method of claim 3, wherein annealing the semiconductor fins further comprises:
providing an ambient that comprises a gas comprising hydrogen at about 900 degrees Celsius and a pressure of about 15 mtorr.

6. The method of claim 1, wherein forming the gate stack comprises:
forming a gate dielectric that surrounds the nanowires; and
forming a gate electrode that surrounds the gate dielectric.

7. The method of claim 1, wherein etching the gate stack to sever the planar nanowires from the source and from the drain comprises leaving portions of the planar nanowires in the etched gate stack, wherein the portions of the planar nanowire are surrounded by the gate stack and form a gate-all-around structure.

8. The method of claim 1, wherein reconnecting the source and the drain to the portions of the planar nanowires in the gate stack comprises epitaxially growing the portions to connect them to the source and the drain.

9. The method of claim 1, wherein reconnecting the source and the drain to the portions of the nanowires in the gate stack comprises epitaxially growing crystals seeded from a crystal facet on the portions in the gate stack.

10. The method of claim 1, wherein the planar nanowires comprise at least one of silicon (Si), germanium (Ge), gallium (Ga), silicon-germanium (SiGe), silicon-carbon (SiC), silicon-germanium carbon (SiGeC), indium phosphide (InP), gallium arsenide (GaAs), gallium nitride (GaN), indium antimonide (InSb), gallium indium arsenide (GaInAs), or gallium aluminum arsenide (GaAlAs).

11. A method of fabricating a semiconductor device comprising:
forming a source and a drain separated by a gap over a semiconductor substrate;
forming at least one planar semiconductor structure in the gap, wherein the at least one planar semiconductor structure contacts the source and the drain;
forming a dielectric layer surrounding the planar semiconductor structure;
forming a conductive layer surrounding the dielectric layer, wherein the planar semiconductor structure, the dielectric layer, and the conductive layer form a gate-all-around structure;
severing the at least one planar semiconductor structure from the source and the drain, wherein a portion of the planar semiconductor structure remains in the gap;
forming a first semiconductor structure that contacts the planar semiconductor structure and the source; and
forming a second semiconductor structure that contacts the planar semiconductor structure and the drain region.

12. The method of claim 11, wherein forming the source and the drain separated by the gap over a semiconductor substrate comprises:
providing an insulating layer on the semiconductor substrate, wherein overlaying the insulating layer is the source, the drain and the gap;

13. The method of claim 11, wherein forming at least one planar semiconductor structure in the gap comprises:
forming at least one nanowire in the planar semiconductor structure in the gap;

14. The method of claim 13, wherein forming the at least one nanowire in the planar semiconductor structure in the gap comprises:
forming a semiconductor fin in the planar semiconductor structure; and
annealing the semiconductor fin to form the nanowire, where in the nanowire comprises a circular cross-section.

15. The method of claim 11, wherein severing the at least one planar semiconductor structure from the source and the drain comprises:
providing the dielectric layer and the conductive layer as a gate stack; and
patterning and etching the gate stack to sever the at least one planar semiconductor structure from the source and the drain, wherein a portion of the planar semiconductor structure remains in the gap.

16. The method of claim 11, forming the first and the second semiconductor structure that contacts the planar semiconductor structure and the source or the drain comprises:
epitaxially growing the at least one nanowire from the portion of the planar semiconductor structure remaining in the gap to the source or the drain;

17. A semiconductor device comprising:
a source;
a drain; and
a gate coupled to the source and the drain by a plurality of nanowires, wherein each of the nanowires comprises a semiconductor structure surrounded by a dielectric layer, and wherein each of the dielectric layers is surrounded by a conductive layer.

18. The semiconductor device of claim 17, wherein the plurality of nanowires are epitaxially grown nanowires.

19. The semiconductor device of claim 18, wherein the crystal orientation of the epitaxially grown plurality of nanowires matches the crystal orientation of the source and the drain.

20. The semiconductor device of claim 19, wherein the crystal orientation of the epitaxially grown plurality of nanowires matches the crystal orientation of the source and drain regions, wherein the matched nanowires meet at the source and drain regions.

21. The semiconductor device of claim 19, wherein each of the nanowires comprises a semiconductor structure surrounded by a dielectric layer, and wherein each of the dielectric layers is surrounded by a conductive layer comprises:
a gate-all-around structure.
